(19) United States
(12) Patent Application Publication
(10) Pub. No.: US 2019/0148290 A1
(43) Pub. Date: May 16, 2019

(54) Two-Dimensional Via Pillar Structures

(71) Applicant: Taiwan Semiconductor Manufacturing Co., Ltd., Hsinchu (TW)

(72) Inventors: Chun-Yao KU, Taipei City (TW); Wen-Hao CHEN, Hsinchu City (TW); Ming-Tao Yu, Hsinchu City (TW)

(73) Assignee: Taiwan Semiconductor Manufacturing Co., Ltd., Hsinchu (TW)

(21) Appl. No.: 16/023,711

(22) Filed: Jun. 29, 2018

Related U.S. Application Data
(60) Provisional application No. 62/586,475, filed on Nov. 15, 2017.

(51) Int. Cl. H01L 23/522; H01L 23/528; H01L 21/768

(52) U.S. Cl. CPC H01L 23/5226; H01L 21/76877; H01L 23/5283

(57) ABSTRACT

Exemplary embodiments for various via pillar structures include one or more first conductors in a first interconnect layer of a semiconductor stack interconnected with one or more second conductors in a second interconnect layer of the semiconductor stack. The one or more first conductors and/or the one or more second conductors within the first interconnect layer and the second interconnect layer, respectively, can traverse multiple directions. In some situations, this allows multiple interconnections to be utilized to interconnect the one or more first conductors and the one or more second conductors. These multiple interconnections can reduce resistance between the one or more first conductors and the one or more second conductors thereby improving performance of signals flowing between the one or more first conductors and the one or more second conductors.

### CROSS-REFERENCE TO RELATED APPLICATIONS

The present application claims the benefit of U.S. Provisional Patent Appl. No.

62/586,475, filed Nov. 15, 2017, which is incorporated herein by reference in its entirety.

### BACKGROUND

The continued improvement of semiconductor fabrication processes has allowed manufacturers and designers to create smaller, more powerful electronic devices. The semiconductor fabrication processes have progressed from a 10 μm semiconductor fabrication process that was reached around 1971 to a 22 nm semiconductor fabrication process that was reached around 2012. The semiconductor device fabrication processes are expected to further progress onto a 5 nm semiconductor fabrication process around 2019. However, with each progression of the semiconductor fabrication process, new challenges in creating integrated circuits have been uncovered. Often times, the semiconductor fabrication process prescribes one or more electronic design constraints imposed on the fabrication of the electronic devices. One such electronic design constraint relates to spacing between conductors within conductive layers of a semiconductor stack. To ensure this electronic design constraint is satisfied, one of the conductive layers of the semiconductor stack is designated to include conductors in a horizontal direction while another one of the conductive layers of the semiconductor stack is designated only to include conductors in a vertical direction. By interconnecting the conductors in the horizontal direction and the conductors in the vertical direction, various components of the electronic devices can be interconnected to form the electronic devices. However, in some situations, these interconnections between the conductors in the horizontal direction and the conductors in the vertical direction can undesirably degrade signals flowing through these conductors; thereby, degrading performance of the electronic devices. For example, resistances of the conductors and their associated interconnections can be characterized as being inversely proportional to their physical sizes. When semiconductor fabrication process continues to progress, the physical size of conductors and their associated interconnections become smaller, thus, increasing their resistance. In addition, resistances of the interconnections have undesirably increased degrading performance of the electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an exemplary semiconductor stack according to an exemplary embodiment of the present disclosure;

FIG. 2A through FIG. 2P illustrate top-down views of various exemplary two-dimensional via pillar structures according to exemplary embodiments of the present disclosure;

FIG. 3 illustrates a block diagram of an electronic design platform according to an exemplary embodiment of the present disclosure;

FIG. 4 illustrates a block diagram of an exemplary computer system for implementing the exemplary design platform according to an exemplary embodiment of the present disclosure; and

FIG. 5 illustrates a flowchart of exemplary operation for manufacturing the exemplary via pillar structures according to an exemplary embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition does not in itself dictate a relationship between the various embodiments and/or configurations discussed.

Overview

Exemplary embodiments for various via pillar structures include one or more first conductors in a first interconnect layer of a semiconductor stack interconnected with one or more second conductors in a second interconnect layer of the semiconductor stack. The one or more first conductors and/or the one or more second conductors within the first interconnect layer and the second interconnect layer, respectively, can traverse multiple directions. In some situations, this allows multiple interconnections, such as vias, to be utilized to interconnect the one or more first conductors and the one or more second conductors. These multiple interconnections can reduce resistance between the one or more first conductors and the one or more second conductors thereby improving performance of signals flowing between the one or more first conductors and the one or more second conductors.

Exemplary Semiconductor Stack

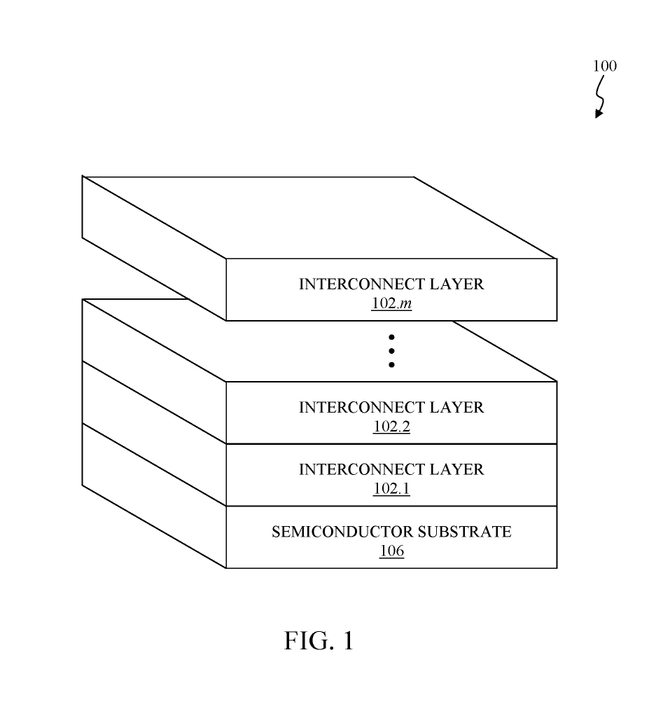

FIG. 1 illustrates a block diagram of an exemplary semiconductor stack according to an exemplary embodiment of the present disclosure. As illustrated in FIG. 1, an exemplary semiconductor stack 100 includes one or more interconnect layers 102.1 through 102.m. The one or more interconnect layers 102.1 through 102.m can include one or more conductive layers, such as one or more metal routing layers to provide an example. The one or more metal routing layers can include one or more conductive materials such as tungsten (W), aluminum (Al), copper (Cu), gold (Au), silver (Ag), platinum (Pt) and/or any other known metal that will be apparent to those skilled in the relevant art(s) without departing from the spirit and scope of the present disclosure. The one or more interconnect layers 102.1 through 102.m can additionally, or alternatively, include one or more non-conductive layers, such as one or more dielectric layers to provide an example. The one or more dielectric layers can include can include one or more dielectric materials such as silicon oxide, spin-on-glass, silicon nitride, silicon carbide, silicon carbon nitride, silicon oxynitride, silicon oxycarbide, silicon carbon nitride fluorine-doped silicate glass (FSG), a low-k dielectric material, and/or any other known dielectric that will be apparent to those skilled in the relevant art(s) without departing from the spirit and scope of the present disclosure. Furthermore, the one or more interconnect layers 102.1 through 102.m can include one or more interconnections, such as one or more via structures to provide an example, to electrically and/or mechanically interconnect various interconnect layers from among the interconnect layers 102.1 through 102.m. The one or more via structures can be implemented as one or more through hole vias, one or more blind vias, one or more buried vias, or any other suitable via structures that will be apparent to those skilled in the relevant art(s) without departing from the spirit and scope of the present disclosure. Moreover, those skilled in the relevant art(s) will recognize the configuration and arrangement of the exemplary semiconductor stack 100 as illustrated in FIG. 1 is for exemplary purposes only. Those skilled in the relevant art(s) will recognize other configurations and arrangements for the one or more interconnect layers 102.1 through 102.m are possible without departing from the spirit and scope of the present disclosure.

In the exemplary embodiment illustrated in FIG. 1, the one or more interconnect layers 102.1 through 102.m are situated above, for example, onto, a semiconductor substrate 106. The semiconductor substrate 106 can be a thin slice of semiconductor material, such as a silicon crystal, but can include other materials, or combinations of materials, such as sapphire or any other suitable material that will be apparent to those skilled in the relevant art(s) without departing from the spirit and scope of the present disclosure. In an exemplary embodiment, the exemplary semiconductor stack 100 can further include one or more diffusion layers and/or one or more polysilicon layers. In this exemplary embodiment, one or more semiconductor components, such as one or more active components, for example, one or more transistors, one or more passive components, for example, one or more resistors, one or more capacitors, and/or one or more inductors, and/or one or more or other suitable components that will be apparent to those skilled in the relevant art(s) can be formed using the one or more diffusion layers and/or one or more polysilicon layers. In some situations, the one or more semiconductor components can be interconnected to each other and/or to other semiconductor components using the one or more interconnect layers 102.1 through 102.m to form one or more integrated circuits.

Exemplary Two-Dimensional via Pillar Structures

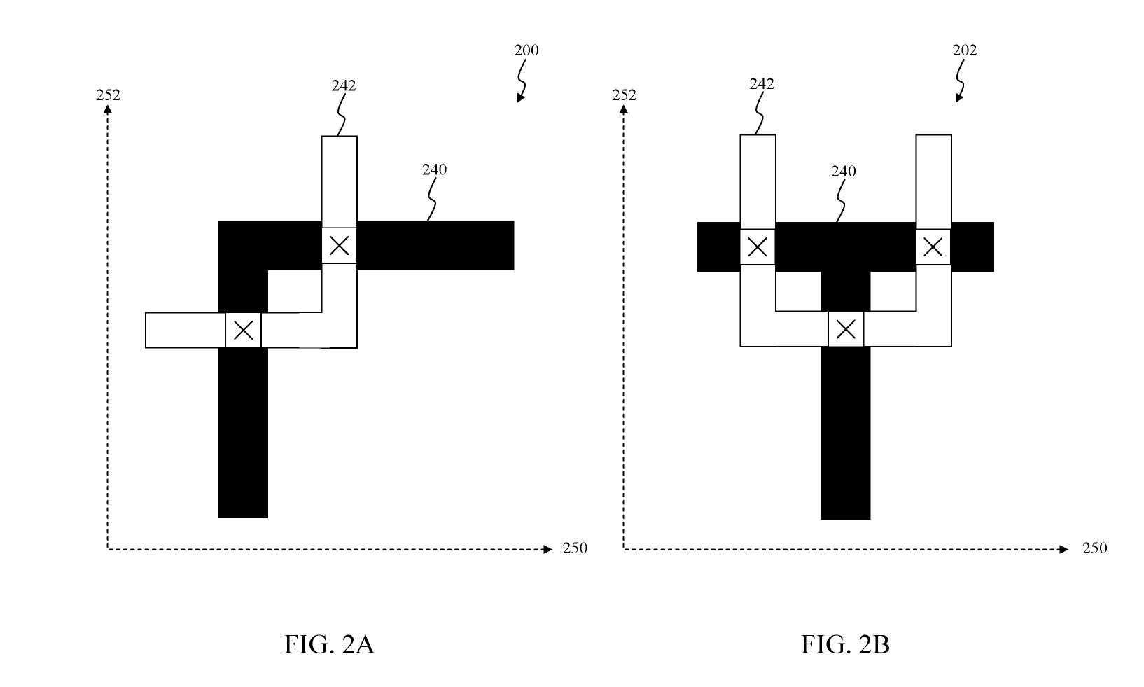

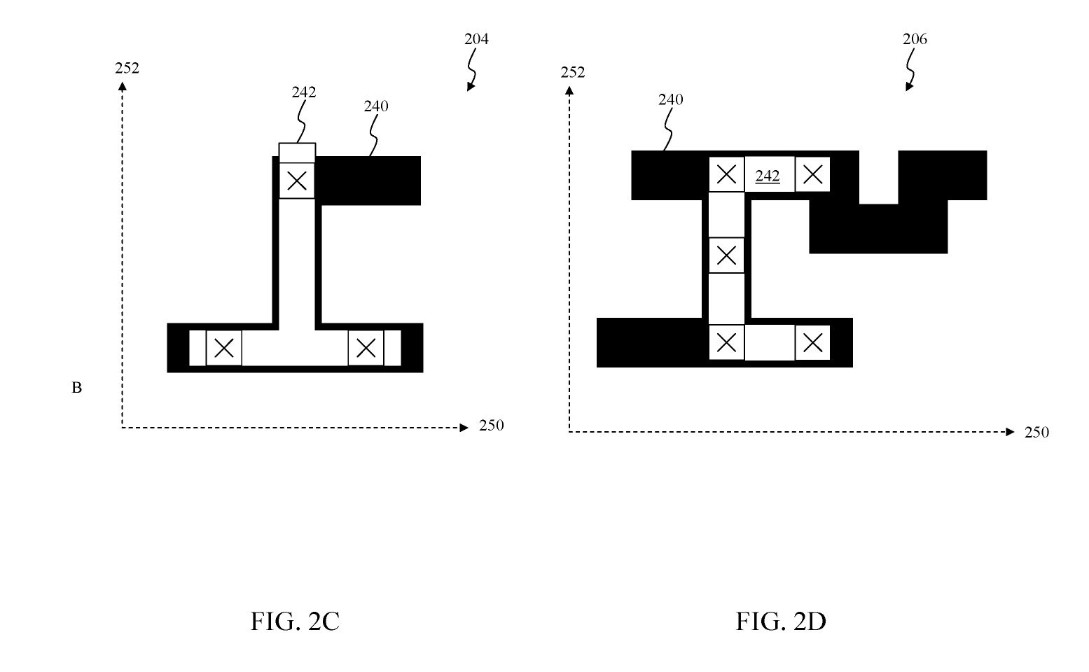

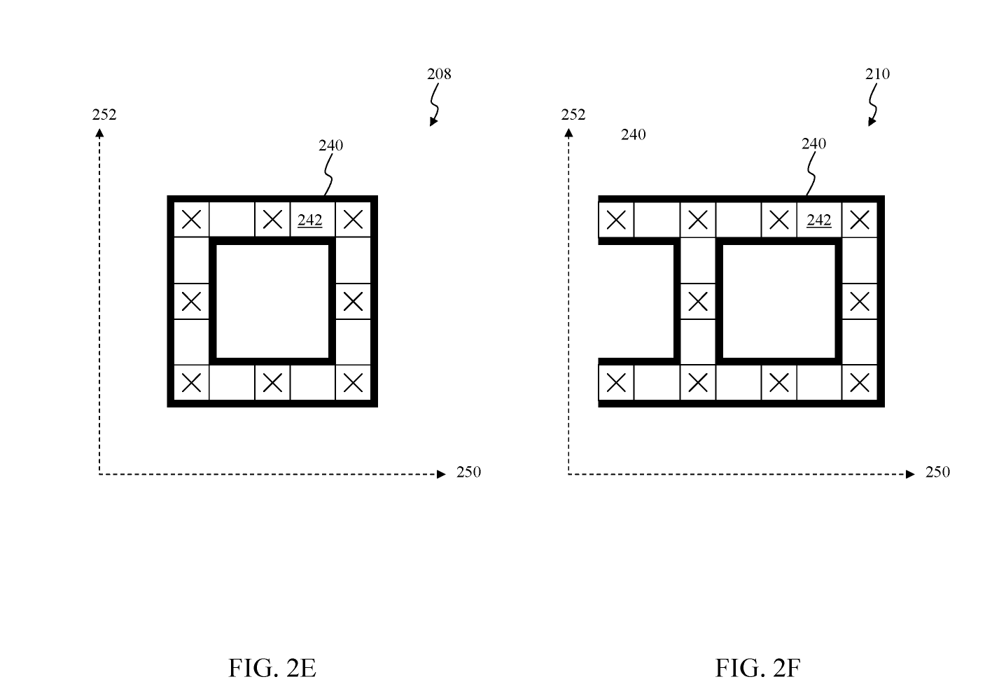

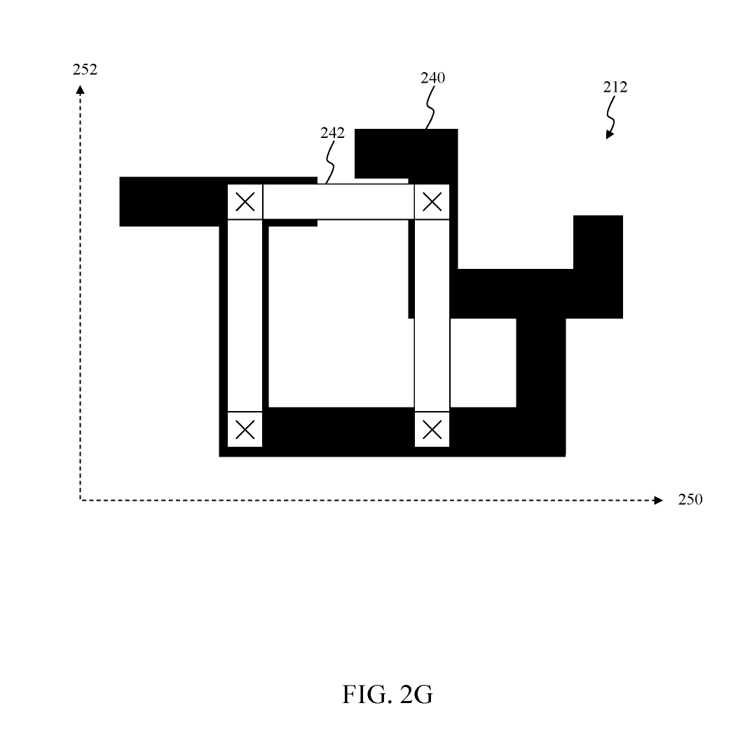

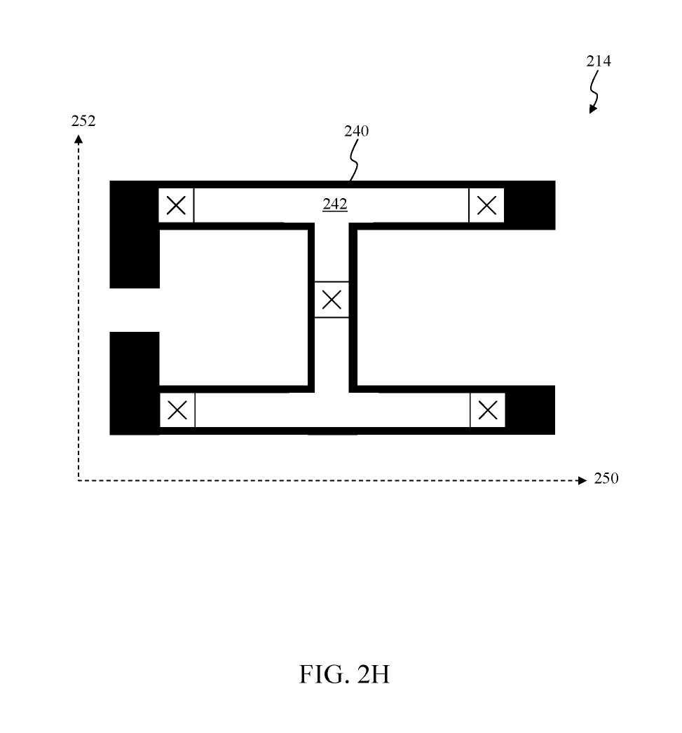

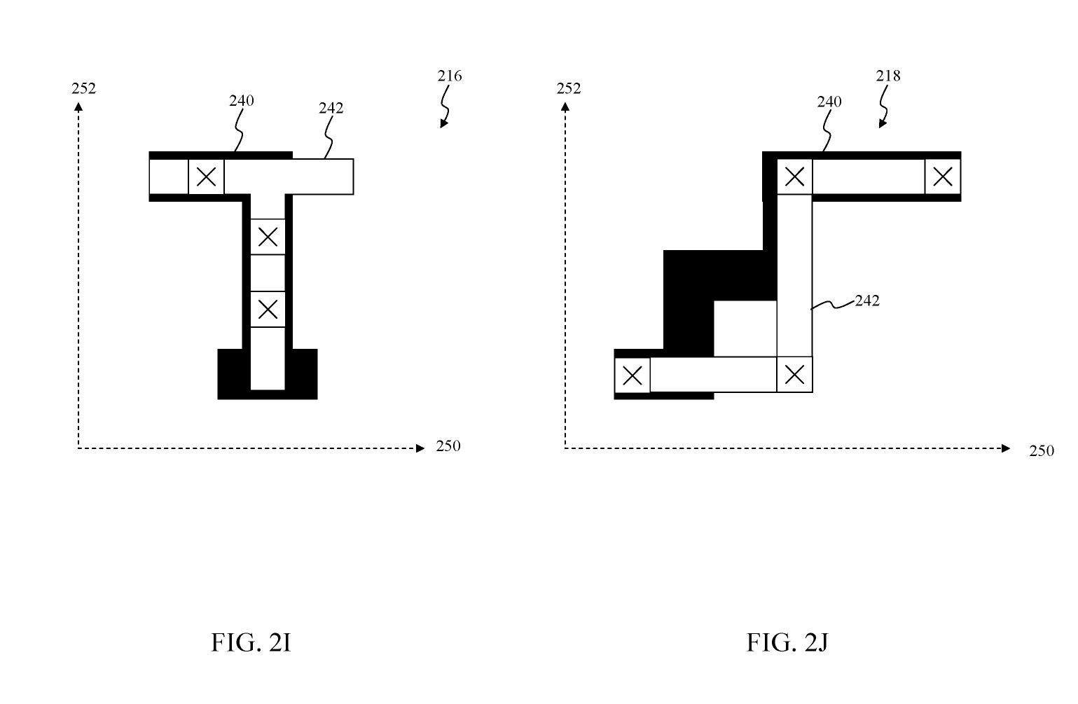

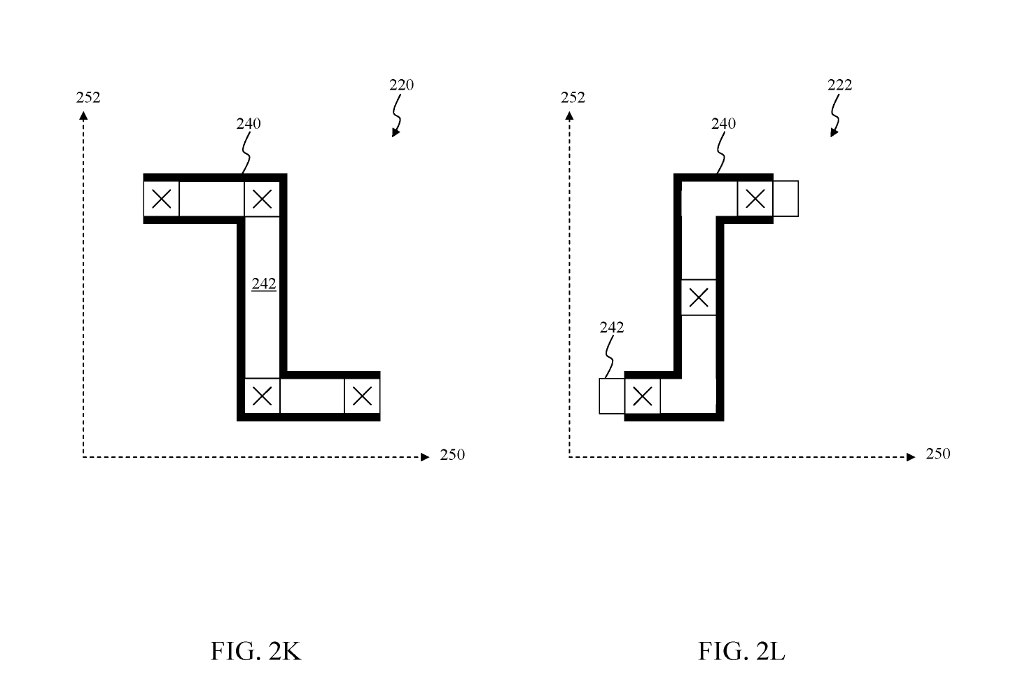

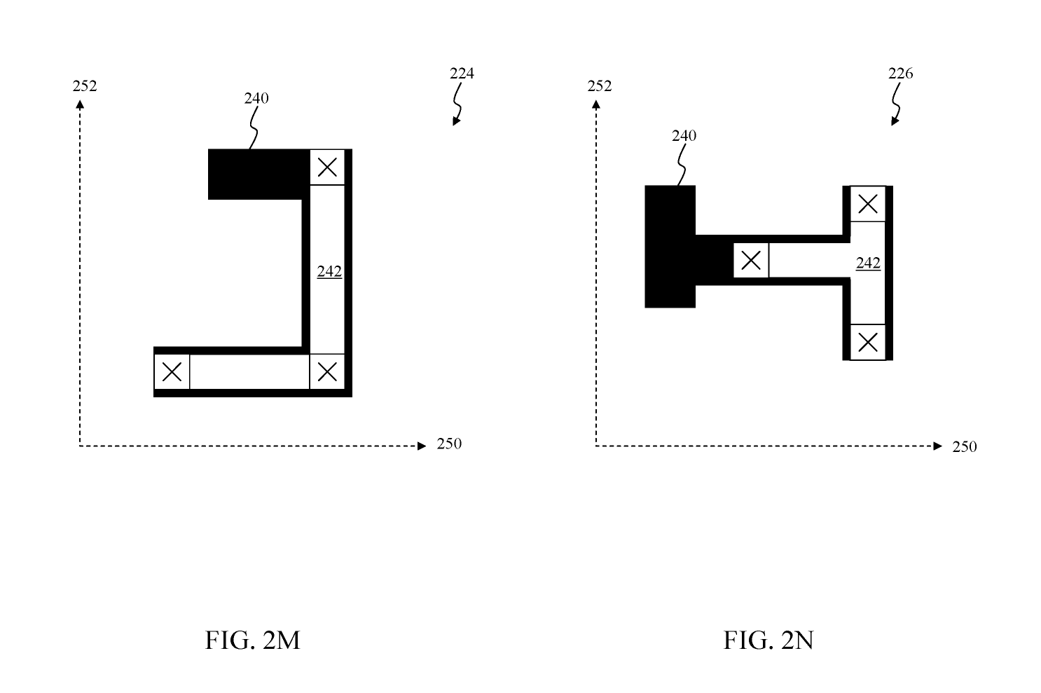

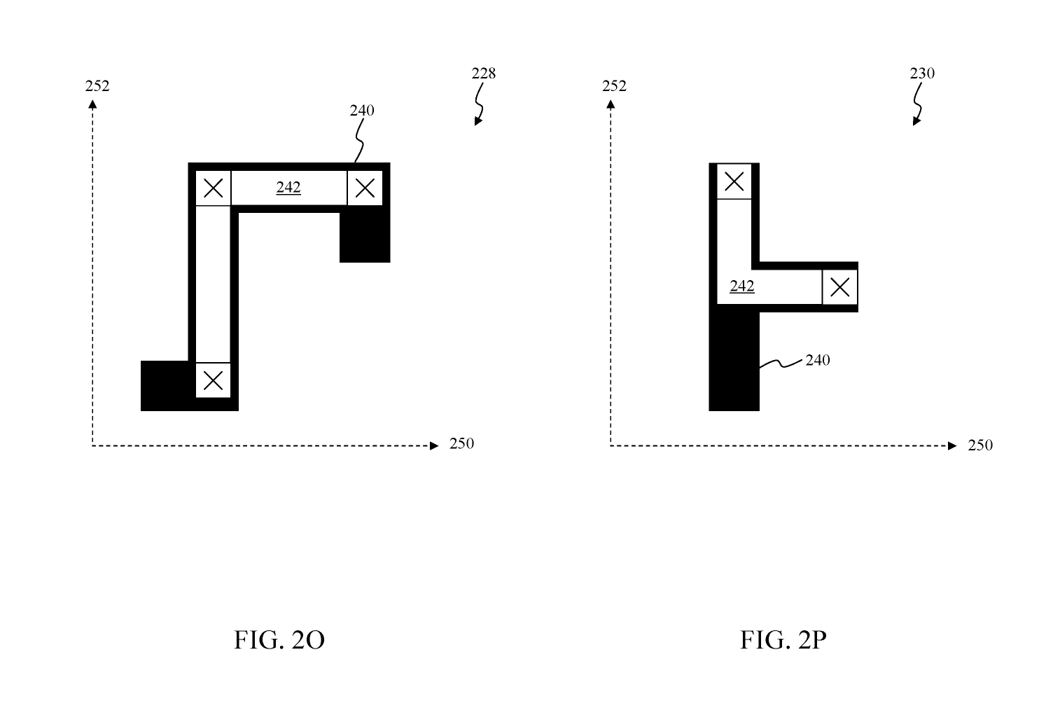

FIG. 2A through FIG. 2P illustrate top-down views of various exemplary two-dimensional via pillar structures according to exemplary embodiments of the present disclosure. As illustrated in FIG. 2A through FIG. 2P, two-dimensional via pillar structures 200 through 230 include a first conductor 240 of the one or more conductive materials formed in a first interconnect layer of a semiconductor stack, such as the semiconductor stack 100 to provide an example, and a second conductor 242 of the one or more conductive materials formed in a second interconnect layer of the semiconductor stack. Herein, the terms “first interconnect layer” and “second interconnect layer” are merely used to distinguish between interconnect layers of the semiconductor layer stack. The terms “first interconnect layer” and “second interconnect layer” need not be the first interconnect layer and the second interconnect layer, respectively, of the semiconductor layer stack. Rather, those skilled in the relevant art(s) will recognize the terms “first interconnect layer” and “second interconnect layer” can be any two interconnect layers of the semiconductor layer stack. In an exemplary embodiment, the first interconnect layer and the second interconnect layer represent two conductive layers, such as two metal routing layers to provide an example, within the semiconductor stack. For convenience, the first conductor is illustrated using a black shading and the second conductor is illustrated using a white shading in FIG. 2A through FIG. 2P. Additionally, widths of the first conductor 240 and the second conductor 242 are not drawn to scale in FIG. 2A through 2P. For example, widths of the first conductor 240 have been exaggerated in FIG. 2A through FIG. 2P for illustrative purposes as will be recognized by those skilled in the relevant art(s) without departing from the spirit and scope of the present disclosure. As illustrated in FIG. 2A through FIG. 2P, the first interconnect layer having the first conductor 240 is situated below the second interconnect layer having the second conductor 242 within the semiconductor layer stack. This exaggeration of the widths of the first conductor 240 allows the first conductor 240 to be visible in FIG. 2A through 2P. However, those skilled in the relevant art(s) will recognize that the widths of the first conductor 240 can be approximately equal to widths of the second conductor 242 and/or the widths of the first conductor 240 can be less than the widths of the second conductor 242 without departing from the spirit and scope of the present disclosure.

As additionally illustrated in FIG. 2A through FIG. 2P, the first conductor 240 traverses multiple directions within the first interconnect layer and the second conductor 242 similarly traverses multiple directions within the second interconnect layer. For example, the first conductor 240 traverses in a first direction 250 and a second direction 252 within the first interconnect layer as illustrated in FIG. 2A through FIG. 2P. In this example, the second conductor 242 similarly traverses in the first direction 250 and the second direction 252 within the second interconnect layer. In some of the exemplary embodiments illustrated in FIG. 2A through FIG. 2P, the first conductor 240 can be considered asymmetric to an axis of symmetry traversing through the two-dimensional via pillar structures 200 through 230 and the second conductor 242 can be considered asymmetric to this axis of symmetry. For example, the axis of symmetry can traverse in the second direction 252 to separate the second conductor 242 into two approximately equal portions of the one or more conductive materials in the two-dimensional via pillar structure 204 as illustrated in FIG. 2C. In this example, as illustrated in FIG. 2C, the first conductor 240 can be considered asymmetric to the axis of symmetry vertically traversing through the second conductor 242 in the second direction 252 and the second conductor 240 can be considered symmetric to the axis of symmetry vertically traversing through the second conductor 242 in the second direction 252. As another example, the axis of symmetry can traverse in the first direction 250 to separate the second conductor 242 into two approximately equal portions of the one or more conductive materials in the two-dimensional via pillar structure 206 as illustrated in FIG. 2D. In this other example, as illustrated in FIG. 2D, the first conductor 240 can be considered asymmetric to the axis of symmetry horizontally traversing through the second conductor 242 in the first direction 250 and the second conductor 240 can be considered symmetric to the axis of symmetry horizontally traversing through the second conductor 242 in the first direction 250.

Furthermore, the first conductor 240 and the second conductor 242 are interconnected using multiple interconnections, such as the multiple via structures as described above in FIG. 1 to provide an example, which illustrated using a squared “x” in FIG. 2A through FIG. 2P, to form the two-dimensional via pillar structures 200 through 230. The multiple via structures represent multiple electrical connections, such as one or more through hole vias, one or more blind vias, one or more buried vias, or any other suitable via structures that will be apparent to those skilled in the relevant art(s) without departing from the spirit and scope of the present disclosure to provide some examples, to interconnect the first conductor 240 and the second conductor 242.

Generally, the first conductor 240 can be characterized as a first sequence of interconnected piecewise segments of the one or more conductive materials that traverses between the first direction 250 and the second direction 252 within the first interconnect layer and the second conductor 242 can be characterized as a second sequence of interconnected piecewise segments of the one or more conductive materials that traverses between the first direction 250 and the second direction 252 within the second interconnect layer. For example, as illustrated in FIG. 2A, the first conductor 240 can be characterized as a first sequence of piecewise segments of the one or more conductive materials having a first segment that traverses the first direction 250 and a second segment that traverses the second direction 252 within the first interconnect layer. In this example, the second conductor 242 can be characterized as a second sequence of piecewise segments of the one or more conductive materials having a first segment that traverses the first direction 250 and a second segment that traverses the second direction 252 within the second interconnect layer.

In some situations, as illustrated in FIG. 2A through FIG. 2P, the multiple via structures are situated between overlaps between the first sequence of piecewise segments of the first conductor 240 and second sequence of piecewise segments of the second conductor 242 to electrically and/or mechanically interconnect the first conductor 240 and the second conductor 242. The multiple via structures as illustrated in FIG. 2A through FIG. 2P are for illustrative purposes only. Those skilled in the relevant art(s) will recognize more or less via structures can be utilized without departing from the spirit and scope of the present disclosure. For example, as illustrated in FIG. 2A, these overlaps between the first sequence of piecewise segments of the first conductor 240 and the second sequence of piecewise segments of the second conductor 242 can occur at approximate midpoints of the segments from among the first sequence of piecewise segments of the first conductor 240 and the second sequence of piecewise segments of the second conductor 242. In this example, the multiple via structures are situated between the approximate midpoints of the segments to electrically and/or mechanically interconnect the first conductor 240 and the second conductor 242. As another example, as illustrated in FIG. 2D, these overlaps between the first sequence of piecewise segments of the first conductor 240 and the second sequence of piecewise segments of the second conductor 242 can occur at approximate endpoints of the segments from among the first sequence of piecewise segments of the first conductor 240 and the second sequence of piecewise segments of the second conductor 242. In this other example, the multiple via structures are situated between the approximate endpoints of the segments to electrically and/or mechanically interconnect the first conductor 240 and the second conductor 242.

In the exemplary embodiments illustrated in FIG. 2A through FIG. 2P, the multiple via structures can reduce resistance between the first conductor 240 and the second conductor 242 by a factor of proportional to the number of via structures within the two-dimensional via pillar structures 200 through 230 when compared to using a single via structure to interconnect the first conductor 240 and the second conductor 242. Generally, this reduction in resistance can be denoted as:

$${R}_{NEW} = \frac{{R}_{OLD}}{ψ} \qquad ( 1 )$$

where R_{NEW} represents this reduced resistance between the first conductor 240 and the second conductor 242, R_{OLD} resistance between the first conductor 240 and the second conductor 242 having only one via structure between the first conductor 240 and the second conductor 242, and y represents the number of via structures between the first conductor 240 and the second conductor 242. As examples, the two via structures of the two-dimensional via pillar structure 200 can reduce resistance between the first conductor 240 and the second conductor 242 by a factor of two, the three via structures of the two-dimensional via pillar structure 202, the two-dimensional via pillar structure 204, the two-dimensional via pillar structure 216, the two-dimensional via pillar structure 222, the two-dimensional via pillar structure 224, the two-dimensional via pillar structure 226, the two-dimensional via pillar structure 228, and the two-dimensional via pillar structure 230 can reduce resistance between the first conductor 240 and the second conductor 242 by a factor of three, the four via structures of the two-dimensional via pillar structure 212, the two-dimensional via pillar structure 218, and the two-dimensional via pillar structure 220 can reduce resistance between the first conductor 240 and the second conductor 242 by a factor of four, the five via structures of the two-dimensional via pillar structure 206 and the two-dimensional via pillar structure 214 can reduce resistance between the first conductor 240 and the second conductor 242 by a factor of five, the eight via structures of the two-dimensional via pillar structure 208 can reduce resistance between the first conductor 240 and the second conductor 242 by a factor of eight, and the ten via structures of the two-dimensional via pillar structure 210 can reduce resistance between the first conductor 240 and the second conductor 242 by a factor of ten. This reduction in the resistance between the first conductor 240 and the second conductor 242 improves performance of signals flowing between the first conductor 240 and the second conductor 242.

Electronic Design Platform for Implementing the Exemplary via Pillar Structures

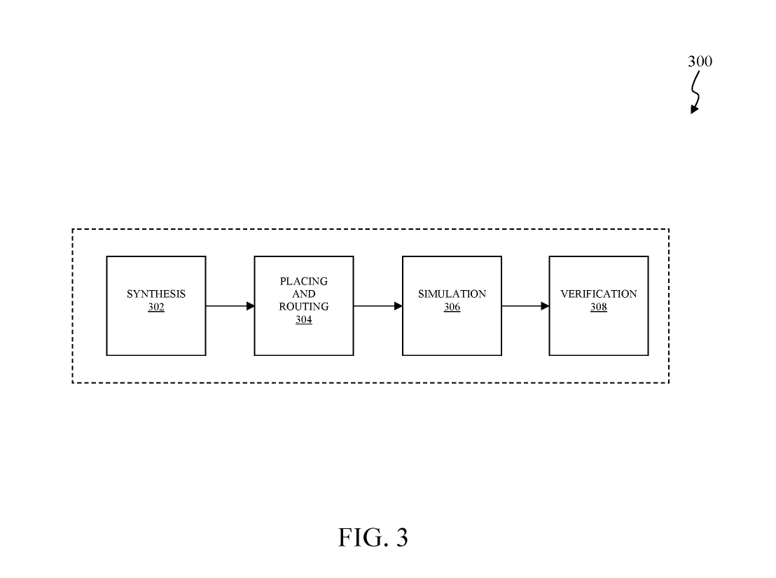

FIG. 3 illustrates a block diagram of an electronic design platform according to an exemplary embodiment of the present disclosure. As illustrated in FIG. 3, an electronic design platform 300 represents a design flow including one or more electronic design software applications, that when executed by one or more computing devices, processors, controllers, or other devices that will be apparent to those skilled in the relevant art(s) without departing from the spirit and the scope of the present disclosure, can design, simulate, analyze, and/or verify one or more high-level software level descriptions of analog and/or digital circuitry for an electronic device. In an exemplary embodiment, the one or more high-level software level descriptions can be implemented using a high-level software language, such as a graphical design application, for example C, System C, C++, LabVIEW, and/or MATLAB, a general purpose system design language, such as like SysML, SMDL and/or SSDL, or any other suitable high-level software or general purpose system design language that will be apparent to those skilled in the relevant art(s) without departing from the spirit and the scope of the present disclosure, or a high-level software format, such as Common Power Format (CPF), Unified Power Formant (UPF), or any other suitable high-level software format that will be apparent to those skilled in the relevant art(s) without departing from the spirit and the scope of the present disclosure. In the exemplary embodiment illustrated in FIG. 3, the electronic design platform 300 includes a synthesis application 302, a placing and routing application 304, a simulation application 306, and a verification application 308.

Moreover, embodiments of the disclosure can be implemented in hardware, firmware, software, or any combination thereof. Embodiments of the disclosure can also be implemented as instructions stored on a machine-readable medium, which can be read and executed by one or more processors. A machine-readable medium can include any mechanism for storing or transmitting information in a form readable by a machine (e.g., a computing device). For example, a machine-readable medium can include non-transitory machine-readable mediums such as read only memory (ROM); random access memory (RAM); magnetic disk storage media; optical storage media; flash memory devices; and others. As another example, the machine-readable medium can include transitory machine-readable medium such as electrical, optical, acoustical, or other forms of propagated signals (e.g., carrier waves, infrared signals, digital signals, etc.). Further, firmware, software, routines, instructions can be described herein as performing certain actions. However, it should be appreciated that such descriptions are merely for convenience and that such actions in fact result from computing devices, processors, controllers, or other devices executing the firmware, software, routines, instructions, etc. In an exemplary embodiment, the synthesis application 302, the placing and routing application 304, the simulation application 306, and the verification application 308 represent one or more electronic design software applications, which when executed by one or more computing devices, processors, controllers, or other devices that will be apparent to those skilled in the relevant art(s) without departing from the spirit and the scope of the present disclosure, configure the one or more computing devices, the processors, the controllers, or the other devices from being general purpose electronic devices into special purpose electronic devices to execute one or more of these applications as to be described in further detail below.

The synthesis application 302 translates one or more characteristics, parameters, or attributes of the electronic device into one or more logic operations, one or more arithmetic operations, one or more control operations, and/or any other suitable operation or operations that will be apparent to those skilled in the relevant art(s) without departing from the spirit and the scope of the present disclosure into the one or more high-level software level descriptions in terms of analog circuitry and/or digital circuitry of the electronic device. The synthesis application 302 can utilize a simulation algorithm to simulate the one or more logic operations, one or more arithmetic operations, one or more control operations, and/or the other suitable operation or operations to verify the one or more logic operations, one or more arithmetic operations, one or more control operations, and/or the other suitable operation perform in accordance with one or more characteristics, parameters, or attributes of the electronic device as outlined in an electronic design specification.

The placing and routing application 304 translates the one or more high-level software level descriptions to form an electronic architectural design for the analog circuitry and/or the digital circuitry of the electronic device. The placing and routing application 304 selectively chooses among one or more standard cells within libraries of standard cells to translate the one or more logic operations, the one or more arithmetic operations, the one or more control operations, and/or the other suitable operation or operations of the one or more high-level software level descriptions into geometric shapes and/or the interconnections between the geometric shapes to form the electronic architectural design for the analog circuitry and/or the digital circuitry of the electronic device. Generally, the one or more standard cell variations have similar functionality as their corresponding standard cell but are different from their corresponding standard cell in terms of the geometric shapes, the locations of the geometric shapes, and/or the interconnections between the geometric shapes.

After selecting the one or more standard cells from the among libraries of standard cells, the placing and routing application 304 places the one or more selected standard cells onto an electronic device design real estate. In an exemplary embodiment, the placing and routing application 304 places one or more conductors of the one or more conductive materials traversing through multiple interconnect layers to interconnect the one or more selected standard cells to form the electronic architectural design for the analog circuitry and/or the digital circuitry of the electronic device. In this exemplary embodiment, the placing and routing application 304 can thereafter place two-dimensional via pillar structures, such as one or more of the two-dimensional via pillar structures 200 through 230 to provide some examples, to interconnect the one or more conductive routings within different interconnect layers among the multiple interconnect layers.

The simulation application 306 simulates the electronic architectural design for the analog circuitry and/or the digital circuitry of the electronic device to replicate one or more characteristics, parameters, or attributes of the electronic architectural design for the analog circuitry and/or the digital circuitry of the electronic device. In an exemplary embodiment, the simulation application 306 can provide a static timing analysis (STA), a voltage drop analysis, also referred to an IREM analysis, a Clock Domain Crossing Verification (CDC check), a formal verification, also referred to as model checking, equivalence checking, or any other suitable analysis that will be apparent to those skilled in the relevant art(s) without departing from the spirit and the scope of the present disclosure. In a further exemplary embodiment, the simulation application 306 can perform an alternating current (AC) analysis, such as a linear small-signal frequency domain analysis, and/or a direct current (DC) analysis, such as a nonlinear quiescent point calculation or a sequence of nonlinear operating points calculated while sweeping a voltage, a current, and/or a parameter to perform the STA, the IREM analysis, or the other suitable analysis.

The verification application 308 verifies the one or more characteristics, parameters, or attributes of the electronic architectural design for the analog circuitry and/or the digital circuitry of the electronic device as replicated by the simulation application 306 satisfy the electronic design specification. The verification application 308 can also perform a physical verification, also referred to as a design rule check (DRC), to check whether the electronic architectural design for the analog circuitry and/or the digital circuitry of the electronic device satisfies one or more recommended parameters, referred to as design rules, as defined by a semiconductor foundry and/or semiconductor technology node for manufacturing the electronic device.

Exemplary Computer System for Implementing the Exemplary Design Platform

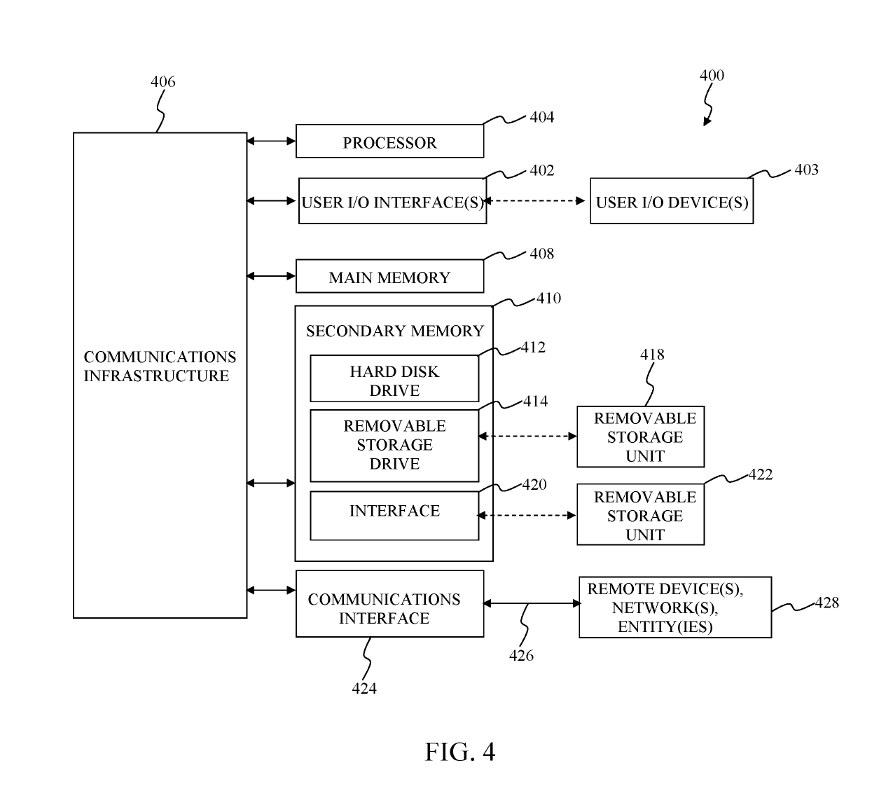

FIG. 4 illustrates a block diagram of an exemplary computer system for implementing the exemplary design platform according to an exemplary embodiment of the present disclosure. A computer system 400 can be used to implement the electronic design platform 100. However, in some situations, more than one computer system 400 can be used to implement the electronic design platform 100. After reading this description, it will become apparent to a person skilled in the relevant art how to implement embodiments using other computer systems and/or computer architectures.

The computer system 400 includes one or more processors 404, also referred to as central processing units, or CPUs, to execute the synthesis application 302, the placing and routing application 304, the simulation application 306, and/or the verification application 308 as described above in FIG. 3. The one or more processors 404 can be connected to a communication infrastructure or bus 406. In an exemplary embodiment, one or more of the one or more processors 404 can be implemented as a graphics processing unit (GPU). The GPU represents a specialized electronic circuit designed to rapidly process mathematically intensive applications on electronic devices. The GPU may have a highly parallel structure that is efficient for parallel processing of large blocks of data, such as mathematically intensive data common to computer graphics applications, images and videos.

The computer system 400 also includes user input/output device(s) 403, such as monitors, keyboards, pointing devices, etc., which communicate with communication infrastructure 406 through user input/output interface(s) 402.

The computer system 400 also includes a main or primary memory 408, such as a random-access memory (RAM) to provide an example. The main memory 408 can include one or more levels of cache. The main memory 408 has stored therein control logic (i.e., computer software) and/or data, such as the synthesis application 302, the placing and routing application 304, the simulation application 306, and/or the verification application 308 as described above in FIG. 3. The computer system 400 can also include one or more secondary storage devices or memory 410 to store the synthesis application 302, the placing and routing application 304, the simulation application 306, and/or the verification application 308 as described above in FIG. 3. The one or more secondary storage devices or memory 410 can include, for example, a hard disk drive 412 and/or a removable storage device or drive 414. The removable storage drive 414 may be a floppy disk drive, a magnetic tape drive, a compact disk drive, an optical storage device, tape backup device, and/or any other storage device/drive. The removable storage drive 414 may interact with a removable storage unit 418. The removable storage unit 418 includes a computer usable or readable storage device having stored thereon computer software (control logic) and/or data. The removable storage unit 418 may be a floppy disk, magnetic tape, compact disk, DVD, optical storage disk, and/any other computer data storage device. The removable storage drive 414 reads from and/or writes to removable storage unit 418 in a well-known manner.

According to an exemplary embodiment, the one or more secondary storage devices or memory 410 may include other means, instrumentalities or other approaches for allowing computer programs and/or other instructions and/or data to be accessed by computer system 400. Such means, instrumentalities or other approaches may include, for example, a removable storage unit 422 and an interface 420. Examples of the removable storage unit 422 and the interface 420 may include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

The computer system 400 may further include a communication or network interface 424. The communication or network interface 424 enables the computer system 400 to communicate and interact with any combination of remote devices, remote networks, remote entities, etc. (individually and collectively referenced by reference number 428). For example, the communication or network interface 424 may allow the computer system 400 to communicate with the remote devices 428 over a communications path 426, which may be wired and/or wireless, and which may include any combination of LANs, WANs, the Internet, etc. Control logic and/or data may be transmitted to and from the computer system 400 via communication path 426.

In an embodiment, a tangible apparatus or an article of manufacture comprising a tangible computer useable or readable medium having control logic (software) stored thereon is also referred to herein as a computer program product or program storage device. This includes, but is not limited to, the computer system 400, the main memory 408, the secondary memory 410, and the removable storage units 418 and 422, as well as tangible articles of manufacture embodying any combination of the foregoing. Such control logic, that when executed by one or more data processing devices (such as computer system 400), causes such data processing devices to operate as described herein.

Based on the teachings contained in this disclosure, it will be apparent to persons skilled in the relevant art(s) how to make and use the invention using data processing devices, computer systems and/or computer architectures other than that shown in FIG. 4. In particular, embodiments may operate with software, hardware, and/or operating system implementations other than those described herein.

Exemplary Fabrication of the Exemplary via Pillar Structures

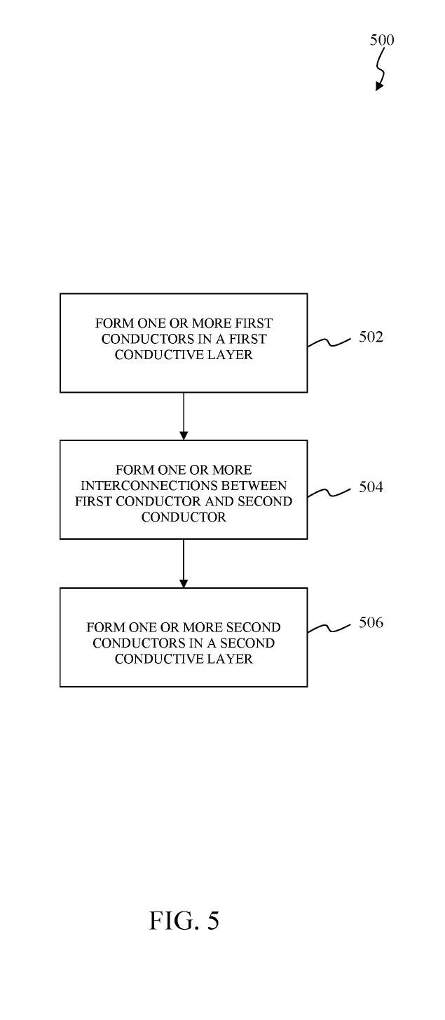

FIG. 5 illustrates a flowchart of exemplary operation for manufacturing the exemplary via pillar structures according to an exemplary embodiment of the present disclosure. The disclosure is not limited to this operational description. Rather, it will be apparent to ordinary persons skilled in the relevant art(s) that other operational control flows are within the scope and spirit of the present disclosure. The exemplary operational control flow 500 represents a multiple-step sequence of photolithographic and chemical processing steps to create the exemplary two-dimensional via pillar structures, such as one or more of the two-dimensional via pillar structures 200 through 230 to provide some examples. The multiple-step sequence of photolithographic and chemical processing steps can include deposition, removal, and/or patterning operations to provide some examples. The deposition operation represents a processing operation where material is grown, coated, or otherwise transferred. The removal represents another processing operation where material is removed. The patterning operation represents a further processing operation where material is shaped or altered.

At operation 502, the operational control flow 500 forms one or more first conductors, such as the first conductor 240 as described above in FIG. 2A through FIG. 2P, to provide some examples, in a first interconnect layer of a semiconductor stack. In the exemplary embodiment illustrated in FIG. 5, the operational control flow 500 transfers a geometric pattern corresponding to the one or more first conductors onto the first interconnect layer. Thereafter, the operational control flow 500 performs a patterning process to remove some of the conductive material from the first interconnect layer in accordance with the geometric pattern to form the one or more first conductors. In an exemplary embodiment, the operational control flow 500 utilizes more advanced semiconductor technology nodes, such as a 12 nm semiconductor technology node to provide an example, to form the one or more first conductors. In this exemplary embodiment, the operational control flow 500 utilizes a next-generation lithography (NGL) technology, such as an Extreme UltraViolet Lithography (EUV) technology, an X-ray lithography technology, an electron beam lithography technology, a focused ion beam lithography technology, and/or a nanoimprint lithography technology to provide some examples, as the patterning process to form the one or more first conductors. In this exemplary embodiment, the use of the NGL technology allows the one or more first conductors to traverse through multiple directions, such as the first direction 250 and the second direction 252 to provide some examples, within the first interconnect layer of the semiconductor stack. For example, achievable resolutions for the NGL technology are less than achievable resolutions of these other, older lithography technology, such as photolithography to provide an example, which only allow the one or more first conductors to traverse through a single direction, such as the first direction 250 or the second direction 252 to provide some examples, within the first interconnect layer of the semiconductor stack.

At operation 504, the operational control flow 500 forms one or more interconnections between the first conductor of operation 502 and a second conductor of operation 506, to be described in further detail below in operation 506. In the exemplary embodiment illustrated in FIG. 5, the operational control flow 500 forms multiple via structures to interconnect the first conductor of operation 502 and the second conductor of operation 506. The multiple via structures represent multiple electrical connections between the first interconnect layer and the second interconnect layer to electrically and/or mechanically and mechanically interconnect the first conductor 308 and the second conductor 310. The multiple via structures can be implemented as one or more through hole vias, one or more blind vias, one or more buried vias, or any other suitable via structures that will be apparent to those skilled in the relevant art(s) without departing from the spirit and scope of the present disclosure.

At operation 506, the operational control flow 500 forms one or more second conductors, such as the second conductor 242 as described above in FIG. 2A through FIG. 2P to provide some examples, in a second interconnect layer of the semiconductor stack to form the exemplary via pillar structure. In an exemplary embodiment, the first interconnect layer represents a lower interconnect layer among the interconnect layers of the semiconductor stack and the second interconnect layer represents an upper interconnect layer among the interconnect layers of the semiconductor stack. In this exemplary embodiment, the lower interconnect layer is situated above a semiconductor substrate of the semiconductor stack and the upper interconnect layer is situated above the lower semiconductor layer. In the exemplary embodiment illustrated in FIG. 5, the operational control flow 500 transfers a geometric pattern corresponding to the one or more second conductors onto the second interconnect layer. Thereafter, the operational control flow 500 performs a patterning process to remove some of the conductive material from the second interconnect layer in accordance with the geometric pattern to form the one or more second conductors. In another exemplary embodiment, the operational control flow 500 utilizes the more advanced semiconductor technology nodes to form the one or more second conductors in a substantially similar manner as the one or more first conductors as described above. In this other exemplary embodiment, the use of the NGL technology allows the one or more second conductors to traverse through multiple directions, such as the first direction 250 and the second direction 252 to provide some examples, within the second interconnect layer of the semiconductor stack. For example, achievable resolutions for the NGL technology are less than achievable resolutions of these other, older lithography technology, such as photolithography to provide an example, which only allow the one or more second conductors to traverse through a single direction, such as the first direction 250 or the second direction 252 to provide some examples, within the second interconnect layer of the semiconductor stack.

### Conclusion

The foregoing Detailed Description discloses a via pillar structure. The via pillar structure includes a first conductor within a first interconnect layer of a semiconductor stack, a second conductor within a second interconnect layer of the semiconductor stack, and multiple via structures electrically and/or mechanically connecting the first conductor and the second conductor. The first conductor traverses a first direction and a second direction within the first interconnect layer of the semiconductor stack and the second conductor traverses the first direction and the second direction within the second interconnect layer of the semiconductor stack.

The foregoing Detailed Description discloses another via pillar structure. This other via pillar structure includes first interconnected piecewise segments of conductive material within a first interconnect layer of a semiconductor stack, second interconnected piecewise segments of the conductive material within a second interconnect layer of the semiconductor stack, and multiple via structures electrically connecting one or more first segments from among the first interconnected piecewise segments and one or more second segments from among the second interconnected piecewise segments. The first interconnected piecewise segments traverses multiple directions within the first interconnect layer of the semiconductor stack and the second interconnected piecewise segments of conductive material traverses the multiple directions within the second interconnect layer of the semiconductor stack.

The foregoing Detailed Description further discloses a method for manufacturing a via pillar structure. The method includes forming a first conductor which traverses a first direction and a second direction within a first interconnect layer of a semiconductor stack, forming a second conductor which traverses the first direction and the second direction within a second interconnect layer of the semiconductor stack, and forming a plurality of via structures to connect the first conductor and the second conductor.

1. A via pillar structure, comprising:
a first conductor within a first interconnect layer of a semiconductor stack, the first conductor traversing a first direction and a second direction within the first interconnect layer of the semiconductor stack;
a second conductor within a second interconnect layer of the semiconductor stack, the second conductor traversing the first direction and the second direction within the second interconnect layer of the semiconductor stack; and
a plurality of via structures connecting the first conductor and the second conductor.

2. The via pillar structure of claim 1, wherein the first direction is perpendicular to the second direction.

3. The via pillar structure of claim 2, wherein the first direction comprises:
an x-axis of a Cartesian coordinate system, and
wherein the second direction comprises:
a y-axis of the Cartesian coordinate system.

4. The via pillar structure of claim 1, wherein the first conductor comprises a first plurality of interconnected piecewise segments, and
wherein the second conductor comprises a second plurality of interconnected piecewise segments.

5. The via pillar structure of claim 4, wherein a first segment from among the first plurality of interconnected piecewise segments overlaps a second segment from among the second plurality of interconnected piecewise segments at approximate midpoints of the first segment and the second segment, and
wherein at least one via structure from among the plurality of via structures is situated between the approximate midpoints to connect the first segment and the second segment.

6. The via pillar structure of claim 4, wherein a first segment from among the first plurality of interconnected piecewise segments overlaps a second segment from among the second plurality of interconnected piecewise segments at approximate endpoints of the second segment, and
wherein at least one via structure from among the plurality of via structures is situated between the approximate endpoints to connect the first segment and the second segment.

7. The via pillar structure of claim 1, wherein the first conductor is characterized as being asymmetric to an axis of symmetry traversing through the via pillar structure, and
wherein the second conductor is characterized as being symmetric to the axis of symmetry traversing through the via pillar structure.

8. The via pillar structure of claim 7, wherein an axis of symmetry traverses through the second conductor in the first direction or the second direction to approximately separate the second conductor into approximately equal portions.

9. A via pillar structure, comprising:
a first plurality of interconnected piecewise segments of conductive material within a first interconnect layer of a semiconductor stack, the first plurality of interconnected piecewise segments traversing a plurality of directions within the first interconnect layer of the semiconductor stack;
a second plurality of interconnected piecewise segments of the conductive material within a second interconnect layer of the semiconductor stack, the second plurality of interconnected piecewise segments of conductive material traversing the plurality of directions within the second interconnect layer of the semiconductor stack; and
a plurality of via structures connecting one or more first segments from among the first plurality of interconnected piecewise segments and one or more second segments from among the second plurality of interconnected piecewise segments.

10. The via pillar structure of claim 9, wherein the plurality of directions comprise:
a first direction; and
a second direction perpendicular to the first direction.

11. The via pillar structure of claim 9, wherein resistance between the one or more first segments and the one or more second segments is proportional to a number of via structures from among the plurality of via structures connecting the one or more first segments and the one or more second segments.

12. The via pillar structure of claim 9, wherein a first segment from among the one or more first segments overlaps a second segment from among the one or more second segments at approximate midpoints of the first segment and the second segment, and
wherein at least one via structure from among the plurality of via structures is situated between the approximate midpoints to connect the first segment and the second segment.

13. The via pillar structure of claim 9, wherein a first segment from among the one or more first segments overlaps a second segment from among the one or more second segments at approximate endpoints of the second segment, and
wherein at least one via structure from among the plurality of via structures is situated between the approximate endpoints to connect the first segment and the second segment.

14. The via pillar structure of claim 9, wherein the first plurality of interconnected piecewise segment is characterized as being asymmetric to an axis of symmetry traversing through the via pillar structure, and
wherein the second plurality of interconnected piecewise segments is characterized as being symmetric to an axis of symmetry traversing through the via pillar structure.

15. The via pillar structure of claim 14, wherein an axis of symmetry traverses through the second plurality of interconnected piecewise segments in a direction from among the plurality of directions to approximately separate the second plurality of interconnected piecewise segments into approximately equal portions.

16. A method for manufacturing a via pillar structure, the method comprising:
forming a first conductor which traverses a first direction and a second direction within a first interconnect layer of a semiconductor stack;
forming a second conductor which traverses the first direction and the second direction within a second interconnect layer of the semiconductor stack; and
forming a plurality of via structures to connect the first conductor and the second conductor.

17. The method of claim 16, wherein the first direction is perpendicular to the second direction.

18. The method of claim 16, wherein resistance between the first conductor and the second conductor is proportional to a number of via structures from among the plurality of via structures connecting the first conductor and the second conductor.

19. The method of claim 16, wherein the forming the first conductor comprises:
forming a first plurality of interconnected piecewise segments within the first interconnect layer of the semiconductor stack,
wherein the forming the second conductor comprises:
forming a second plurality of interconnected piecewise segments within the second interconnect layer of the semiconductor stack,
wherein a first segment from among the first plurality of interconnected piecewise segments overlaps a second segment from among the second plurality of interconnected piecewise segments at approximate midpoints of the first segment and the second segment, and
wherein the forming the plurality of via structures comprises:
forming at least one via structure from among the plurality of via structures between the approximate midpoints to connect the first segment and the second segment.

20. The method of claim 16, wherein the forming the first conductor comprises:
forming a first plurality of interconnected piecewise segments,
wherein the forming the second conductor comprises:
forming a second plurality of interconnected piecewise segments,
wherein a first segment from among the first plurality of interconnected piecewise segments overlaps a second segment from among the second plurality of interconnected piecewise segments at approximate endpoints of the second segment, and
wherein the forming the plurality of via structures comprises:
forming at least one via structure from among the plurality of via structures between the approximate endpoints to connect the first segment and the second segment.
